(19) United States
(12) Patent Application Publication
(10) Pub. No.: US 2021/0121992 A1
(43) Pub. Date: Apr. 29, 2021

(54) SOLDER PASTE AND JOINING STRUCTURE

(71) Applicant: Panasonic Intellectual Property Management Co., Ltd., Osaka (JP)

(72) Inventors: NAOMICHI OHASHI, Hyogo (JP); YASUHIRO OKAWA, Osaka (JP); KOSO MATSUNO, Osaka (JP)

(21) Appl. No.: 17/073,466

(22) Filed: Oct. 19, 2020

(30) Foreign Application Priority Data
Oct. 28, 2019 (JP) 2019-195537

(51) Int. Cl. B23K 35/362; B23K 35/36

(52) U.S. Cl. CPC B23K 35/362; B23K 35/262; B23K 35/3618

(57) ABSTRACT

A solder paste containing a solder powder and a flux, in which the flux contains a keto acid and a hydroxy group-containing compound different from the keto acid, and the keto acid has a melting point of 60° C. or lower, the hydroxy group-containing compound has a melting point of 60° C. or lower and has at least three hydroxy groups in the molecule, and a content of the keto acid, a content of the hydroxy group-containing compound and a content of the solder powder satisfy Expressions (1) and (2),

W₁×⅓≤W₂≤W₁×⅚ (1)

(W₁+W₂)/W₃×100≥2.0 (2)
where W₁ represents a weight (g) of the keto acid, W₂ represents a weight (g) of the hydroxy group-containing compound, and W₃ represents a weight (g) of the solder powder.

### BACKGROUND

### 1. Technical Field

The present disclosure relates to a solder paste for electrically connecting a surface mount component to a circuit board and a joining structure using the same.

### 2. Description of the Related Art

In surface mounting of electronic components, generally, a method in which a solder paste is applied to a printed circuit board by a screen printing method, a dispenser method, or the like, surface mounting components are mounted on the printed circuit board, and the solder paste is heated and melted using a reflow oven or the like to electrically connect the surface mount component to the circuit board is adopted.

A solder paste is produced by mixing a solder alloy powder (hereinafter, referred to as “solder powder”), a rosin (pine resin) or a liquid thermosetting resin, an activator such as an organic acid, and a flux containing a viscosity adjuster, and the like and stirring the mixture.

It is required that even when a solder paste is left in a room temperature environment, the meltability of the solder powder at the time of reflow is not deteriorated. The main cause of the deterioration in the meltability is that the salt forming reaction between the solder powder and the activator proceeds in a room temperature environment and the activator is consumed.

In order to suppress the reaction between the solder powder and the activator in a room temperature environment, for example, Japanese Patent Unexamined Publication No. S63-180396 discloses a method of coating an activator with a substance that decomposes at a soldering temperature higher than the temperature at the time of preheating.

### SUMMARY

According to a first aspect of the present disclosure, there is provided a solder paste containing: a solder powder; and a flux,

in which the flux contains a keto acid and a hydroxy group-containing compound different from the keto acid,

the keto acid has a melting pint of 60° C. or lower,

the hydroxy group-containing compound has a melting point of 60° C. or lower and has at least three hydroxy groups in the molecule, and

a content of the keto acid, a content of the hydroxy group-containing compound, and a content of the solder powder satisfy Expressions (1) and (2),

W₁×⅓≤W₂≤W₁×⅚ (1)

(W₁+W₂)/W₃×100≥2.0 (2)

where W₁ represents a weight (g) of the keto acid, W₂ represents a weight (g) of the hydroxy group-containing compound, and W₃ represents a weight (g) of the solder powder.

### BRIEF DESCRIPTION OF THE DRAWINGS

FIG. 1 is a diagram showing evaluation results of examples and comparative examples of a method for preparing a solder paste.

### DETAILED DESCRIPTIONS

In Japanese Patent Unexamined Publication No. S63-180396, although it is possible to suppress the deterioration in the meltability of the solder powder at the time of reflow due to the consumption of the activator in a room temperature environment to some extent, the oxide film cannot be removed at the time of preheating due to coating of the activator, and thus the meltability of the solder powder at the time of reflow is deteriorated.

The present disclosure has been made in view of such circumstances, and an object thereof is to provide a solder paste capable of sufficiently securing solder meltability at the time of reflow even in a case where the solder paste is stored in a room temperature (25° C.) environment and a joining structure using the same.

Hereinafter, exemplary embodiments of the present disclosure will be described.

A solder paste according to an exemplary embodiment of the present disclosure includes a solder powder and a flux that removes an oxide film of the solder powder.

The solder powder preferably contains two or more elements of Sn, Bi, In, and Ag. For example, tin-based alloys or mixtures of these alloys, for example, an alloy composition selected from the group consisting of Sn—Bi, Sn—In, Sn—Bi—In, Sn—Bi—Sb, Bi—In, Sn—Ag, Sn—Cu, Sn—Ag—Cu, Sn—Ag—Bi, Sn—Cu—Bi, Sn—Ag—Cu—Bi, Sn—Ag—In, Sn—Cu—In, Sn—Ag—Cu—In, and Sn—Ag—Cu—Bi—In, can be used.

In addition, the alloy composition of the solder powder may adopt a single alloy composition, or may be a mixture of different alloy compositions.

The melting point of the solder powder is preferably 170° C. or lower in order to secure the solder meltability at the time of reflow. The melting point is more preferably 150° C. or lower.

The average particle size of the solder powder is preferably 1 to 100 μm in order to secure the solder meltability at the time of reflow. The average particle size is more preferably 10 to 50 μm.

The flux contains an activator having a function of removing a solder oxide film, and a thermosetting resin (or rosin (pine resin)) having a function as a binder for giving paste properties.

The activator contains a keto acid and a hydroxy group (OH group)-containing compound. By forming a hydrogen bond by the carboxyl group of the keto acid and the hydroxy group of the hydroxy group-containing compound, it is possible to suppress the formation of a carboxylic acid-metal salt by the reaction between the solder powder and the carboxyl group in the keto acid.

The melting point of the keto acid is 60° C. or lower. The melting point is more preferably 40° C. or lower. Thus, the keto acid easily has fluidity at 25° C. under atmospheric pressure, and easily forms a hydrogen bond with the hydroxy group-containing compound when mixed with the hydroxy group-containing compound.

It is preferable that the keto acid is contained in an amount of 1.2% by weight or more with respect to the solder powder. Thus, the oxide film of the solder powder generated at the time of reflow can be sufficiently removed. The content of the keto acid is more preferably 3.0% by weight or more. On the other hand, in order to suppress the reaction between the solder powder and the carboxyl group in an environment at 25° C., the content of the keto acid is preferably 7.0% by weight or less with respect to the solder powder. The content of the keto acid is more preferably 6.0% by weight or less.

Examples of the keto acid include α-keto acids such as pyruvic acid, β-keto acids such as acetoacetic acid, and γ-keto acids such as levulinic acid.

The number of carboxyl groups contained in the keto acid is preferably one. In this case, since there are few reaction points, the reaction with the solder powder in an environment at 25° C. can be further suppressed.

The melting point of the hydroxy group-containing compound is 60° C. or lower. The melting point is more preferably 40° C. or lower. Thus, the hydroxy group-containing compound easily has fluidity at 25° C. under atmospheric pressure, and when mixed with the keto acid, a hydrogen bond is easily formed with the keto acid.

The hydroxy group-containing compound has at least three OH groups in the molecule. Thus, a hydrogen bond can be three-dimensionally formed with the keto acid, and the reaction between the solder powder and the carboxyl group can be further suppressed. The number of OH groups in the molecule is preferably small, and a case where the number of OH groups is 3 is most effective.

The content of the hydroxy group-containing compound in the solder paste satisfies Expression (1).

W₁×⅓≤W₂≤W₁×⅚ (1)

W₁ represents the weight (g) of the keto acid, and W₂ represents the weight (g) of the hydroxy group-containing compound.

By satisfying Expression (1), the number of OH groups in the hydroxy group-containing compound can be set to equal to or more than the number of carboxyl groups in the keto acid, and hydrogen bonds are easily formed. On the other hand, the number of OH groups of the hydroxy group-containing compound can be 2.5 times or less the number of carboxyl groups in the keto acid, and a decrease in acidity of the activator can be suppressed.

Further, the hydroxy group-containing compound is preferably contained in an amount of 0.6% by weight or more with respect to the solder powder. Thus, the reaction between the solder powder and the carboxyl group in an environment at 25° C. can be suppressed. The content of the hydroxy group-containing compound is more preferably 1.8% by weight or more. On the other hand, in order to sufficiently remove the oxide film of the solder powder generated at the time of reflow, the content of the hydroxy group-containing compound is preferably 4.1% by weight or less with respect to the solder powder. The content of the hydroxy group-containing compound is more preferably 3.5% by weight or less.

Examples of the hydroxy group-containing compound include glycerin, and triethanolamine

In addition, it is more preferable that the hydroxy group-containing compound contains a nitrogen atom such as triethanolamine Thus, a hydrogen bond is formed by the nitrogen atom and the OH group of the carboxyl group, the reaction between the solder powder and the carboxyl group in an environment at 25° C. can be suppressed, and an increase in the viscosity of the solder paste can be suppressed. In addition, the solder meltability at the time of reflow is easily secured.

In the solder paste, it is necessary that the content of the keto acid, the content of the hydroxy group-containing compound, and the content of the solder powder satisfy Expression (2).

(W₁+W₂)/W₃×100≥2.0 (2)

W₁ represents a weight (g) of the keto acid, and W₂ represents a weight (g) of the hydroxy group-containing compound, and W₃ represents a weight (g) of the solder powder.

By satisfying Expression (2), the contents of the keto acid and the hydroxy group-containing compound are sufficiently secured to the solder powder, and thus the oxide film of the solder powder generated during the reflow can be sufficiently removed.

Further, it is preferable that the content of the keto acid, the content of the hydroxy group-containing compound, and the content of the solder powder satisfy Expression (3).

(W₁+W₂)/W₃×100≤10.0 (3)

By satisfying Expression (3), the content of the solder powder in the solder paste can be sufficiently secured, and the electrical conductivity after solder joining can be kept good.

As described above, the keto acid and the hydroxy group-containing compound preferably form a hydrogen bond at 25° C. The presence or absence of hydrogen bond formation can be detected by a known method such as H-NMR, C-NMR or FT-IR.

As the thermosetting resin contained in the flux, for example, a liquid epoxy resin can be used. As the epoxy resin, for example, bisphenol A type epoxy resins, bisphenol F type epoxy resins, bisphenol S type epoxy resins, glycidyl amine type resins, alicyclic epoxy resins, aminopropane type epoxy resins, biphenyl type epoxy resins, naphthalene type epoxy resins, anthracene type epoxy resins, triazine type epoxy resins, dicyclopentadiene type epoxy resins, triphenylmethane type epoxy resins, fluorene type epoxy resins, phenol aralkyl type epoxy resins, novolac type epoxy resins and the like can be used. These may be used alone or in combination of two or more thereof. In addition, a solid epoxy resin and a liquid epoxy resin can be combined, but it is necessary that the solid epoxy resin and the liquid epoxy resin are liquid at 25° C. under atmospheric pressure, that is, have fluidity.

Further, the flux may contain a solvent. A glycol solvent or the like can be used as the solvent. The solvent may be used alone or in combination of two or more thereof. As the solvent, a suitable solvent is selected according to the use environment and application of the solder paste.

Also, the flux may contain a curing agent. As the curing agent, a compound selected from the group consisting of thiol-based compounds, modified amine-based compounds, polyfunctional phenol-based compounds, imidazole-based compounds, and acid anhydride-based compounds can be used. These may be used alone or in combination of two or more thereof. As the curing agent, a suitable curing agent is selected according to the use environment and application of the solder paste.

The flux may also contain a viscosity adjuster or a thixotropy imparting additive. Examples of inorganic materials may include silica, and alumina. Examples of organic materials may include solid epoxy resins, low molecular amide compounds, polyester resins, organic derivatives of castor oil, and an organic solvent. These may be used alone or in combination of two or more thereof.

The solder paste according to the exemplary embodiment of the present disclosure may contain substances other than the solder powder and the flux within the range in which the object of the present disclosure is achieved.

According to another exemplary embodiment of the present disclosure, a joining structure using the solder paste can be obtained. For example, it is possible to obtain a joining structure in which an electrode of a first member such as a circuit board and an electrode of a second member such as a surface mount component are joined using the solder paste according to the exemplary embodiment of the present disclosure.

For example, the joining structure according to the exemplary embodiment of the present disclosure can be obtained by applying the solder paste according to the exemplary embodiment of the present disclosure to electrodes of a printed circuit board by a screen printing method, a dispenser method, or the like, superposing electrodes of a surface mount component thereon, and heating and melting the solder paste using a reflow oven or the like to join the electrodes of the circuit board and the electrodes of the surface mount component.

Since the meltability of the solder powder in the solder paste is sufficiently secured at the time of reflow, a joining defect between the electrodes of the first member such as a circuit board and the electrodes of the second member such as a surface mount component does not easily occur and electrical connection between both electrodes can be stably secured in the joining structure according to the exemplary embodiment of the present disclosure.

### Examples

Examples and comparative examples of the present disclosure will be shown below. It is to be noted that the forms of the Examples and Comparative Examples of the present disclosure below are merely illustrative, and are not intended to limit the present disclosure in any ways. In the following Examples and Comparative Examples, “parts” and “%” are by weight, unless otherwise specifically stated.

Regarding the raw material of Example 1, spherical particles having a composition 42Sn-58Bi (manufactured by Mitsui Mining & Smelting Co., Ltd., melting point: 139° C., average particle size: 25 μm) were used as a solder powder. Among activators, levulinic acid (manufactured by Tokyo Chemical Industry Co., Ltd.) was used for a keto acid, and glycerin (manufactured by Tokyo Chemical Industry Co., Ltd.) was used for a hydroxy group-containing compound. As a thermosetting resin, a bisphenol F type epoxy resin “806” manufactured by Mitsubishi Chemical Corporation was used. In addition, in order to accelerate the curing of the epoxy resin, “2P4MHZ” manufactured by Shikoku Chemicals Corporation, as an imidazole-based curing agent, was used. As a viscosity adjuster, a castor oil-based additive, “THIXCIN R” manufactured by Elementis Japan was used.

In a method for producing a solder paste of Example 1, 20 parts by weight of the bisphenol F type epoxy resin and 0.5 part by weight of the viscosity adjuster were added, and the viscosity adjuster was dissolved by heating and stirring at 120° C. and cooled to room temperature. 1.0 part by weight of the imidazole-based curing agent, 3.0 parts by weight of levulinic acid, and 1.2 parts by weight of glycerin were added to the mixture, and the mixture was kneaded for 10 minutes with a vacuum planetary mixer to obtain a flux. 100.0 parts by weight of the solder powder was added to the flux, and the mixture was kneaded for 30 minutes with a vacuum planetary mixer to obtain a solder paste.

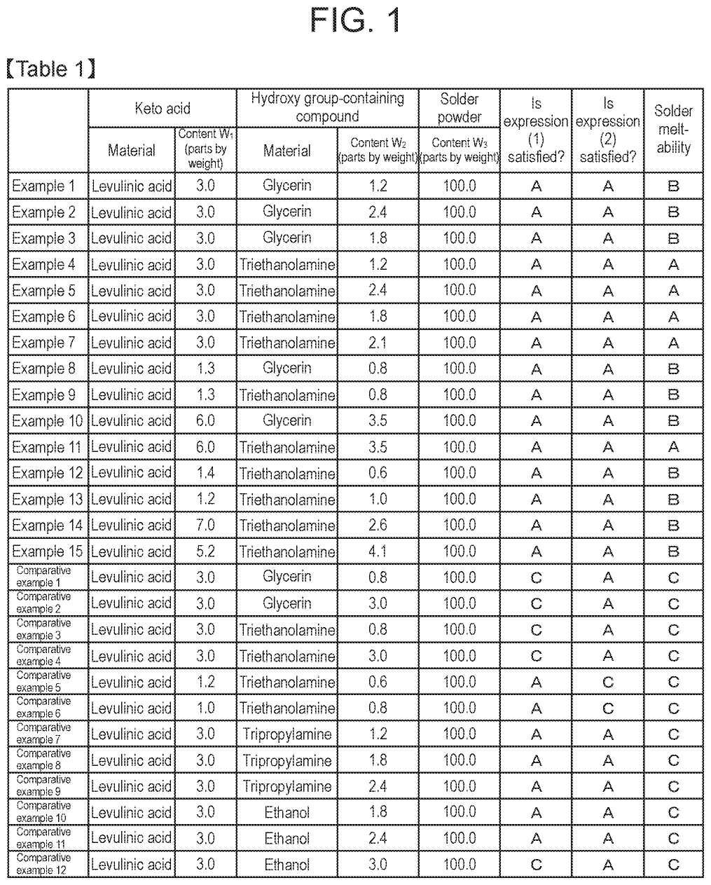

Solder pastes of Examples 2 to 15 and Comparative Examples 1 to 12 were prepared in the same manner as in Example 1 except that the kinds and contents of the keto acid and the hydroxy group-containing compound were changed as shown in Table 1 of FIG. 1. Tripropylamine used in Comparative Examples 7 to 9 was available from Tokyo Chemical Industry Co., Ltd., and ethanol used in Comparative Examples 10 to 12 was available from Wako Pure Chemical Industries, Ltd.

Next, in order to evaluate the solder meltability at the time of reflow, the following simulation was conducted.

In a state in which the solder paste was transferred onto a ceramic plate having a thickness of 0.1 mm in a size of a diameter of 6.5 mm and a thickness of 0.2 mm using a metal mask, the ceramic plate was left at 25° C. for 48 hours and then heated on a hot plate set to 160° C. to melt the solder. A case where solder became one large sphere and solder balls having a diameter of 75 μm or less were not arranged therearound in a semi-continuous ring shape was determined as best (A), a case where solder became one large sphere and solder balls having a diameter of 75 μm or less were arranged therearound in a shape formed to be equal to or smaller than a semicircle was determined as good (B), and a case where solder became one large sphere and solder balls having a diameter of 75 μm or less were arranged therearound in a shape larger than a semicircle or solder did not become one large sphere was determined as poor (C).

The evaluation results are shown in Table 1 of FIG. 1. In addition, a column as to whether or not the content of the keto acid, the content of the hydroxy group-containing compound, and the content of the solder powder satisfy Expressions (1) and (2) was provided. A case where Expressions are satisfied was denoted by A and a case where Expressions are not satisfied was denoted by C. Further, “Tripropylamine” of Comparative Examples 7 to 9 is not a hydroxyl group-containing compound, but is described in the column of “Hydroxyl group-containing compound” for comparison.

The results in Table 1 shown in FIG. 1 are considered.

Examples 1 to 15 are examples in which all the requirements defined in the embodiments of the present disclosure are satisfied, and the solder meltability was good or best. Particularly, in Examples 4 to 7 and 11, it is considered that since the content of the keto acid was 3.0 to 6.0 parts by weight, which is a more preferable range (that is, 3.0 to 6.0% by weight with respect to 100 parts by weight of the solder powder), the hydroxy group-containing compound was triethanolamine containing a nitrogen atom, and the content thereof was 1.8 to 3.5 parts by weight, which is a more preferable range (that is, 1. 8 to 3.5% by weight with respect to 100 parts by weight of the solder powder), the reaction between the solder powder and the carboxyl group in an environment of 25° C. could be further suppressed and the best result was obtained.

On the other hand, Comparative Examples 1 to 12 are examples in which the requirements specified in the present disclosure are not satisfied, and the solder meltability was poor.

Comparative Examples 1 and 3 are examples in which the lower limit of Expression (1), that is, W₁×⅓≤W₂ is not satisfied. In these examples, it is considered that since the amount of the hydroxy group-containing compound was small, a hydrogen bond between the keto acid and the hydroxy group-containing compound was not sufficiently formed, and as a result, the solder meltability was poor.

Comparative Examples 2 and 4 are examples in which the upper limit of Expression (1), that is, W₂≤W₁×⅚ is not satisfied. In these examples, it is considered that since the amount of the hydroxy group-containing compound was excessive, the hydrogen bond was too strong or the acidity of the keto acid was decreased, the function of removing the oxide film during heating was deteriorated, and as a result, the solder meltability was poor.

Comparative Examples 5 and 6 are examples in which Expression (2) is not satisfied. In these examples, it is considered that the total content of the keto acid and the hydroxy group-containing compound was small, the function of removing the oxide film during heating was deteriorated, and as a result, the solder meltability was poor.

Comparative Examples 7 to 9 are examples in which tripropylamine, which is a compound containing no hydroxy group, is used. In these examples, it is considered that since no hydroxy group was contained, a hydrogen bond was not sufficiently formed between the keto acid and tripropylamine, and as a result, the solder meltability was poor.

Comparative Examples 10 to 12 are examples using ethanol, which is a compound containing one hydroxy group (that is, not containing three hydroxy groups). In these examples, it is considered that since the number of hydroxy groups was small, a hydrogen bond between the keto acid and the hydroxy group-containing compound was not sufficiently formed, and as a result, the solder meltability was poor.

According to a first aspect of the present disclosure, there is provided a solder paste containing: a solder powder; and a flux,

in which the flux contains a keto acid and a hydroxy group-containing compound different from the keto acid,

the keto acid has a melting pint of 60° C. or lower,

the hydroxy group-containing compound has a melting point of 60° C. or lower and has at least three hydroxy groups in the molecule, and

a content of the keto acid, a content of the hydroxy group-containing compound, and a content of the solder powder satisfy Expressions (1) and (2),

W₁×⅓≤W₂≤W₁×⅚ (1)

(W₁+W₂)/W₃×100≥2.0 (2)

where W₁ represents a weight (g) of the keto acid, W₂ represents a weight (g) of the hydroxy group-containing compound, and W₃ represents a weight (g) of the solder powder.

According to a second aspect of the present disclosure, in the solder paste according to the first aspect, the keto acid may have one carboxyl group.

According to a third aspect of the present disclosure, in the solder paste according to the first or second aspect, the hydroxy group-containing compound may contain a nitrogen atom.

According to a fourth aspect of the present disclosure, in the solder paste according to any one of the first to third aspects, Expression (3) may be further satisfied.

(W₁+W₂)/W₃×100≤10.0 (3)

According to a fifth aspect of the present disclosure, in the solder paste according to any one of the first to fourth aspects, when the temperature of the solder paste is 25° C., the keto acid and the hydroxy group-containing compound may form a hydrogen bond.

According to a sixth aspect of the present disclosure, in the solder paste according to any one of the first to fifth aspects, the solder powder may contain two or more elements selected from the group consisting of Sn, Bi, In, and Ag and may have a melting point of 170° C. or lower.

According to a seventh aspect of the present disclosure, there is provided a joining structure including a first member and a second member,

in which the first member and the second member each have an electrode, and

the electrode of the first member and the electrode of the second member are joined by the solder paste according to any one of the first to sixth aspects.

According to the embodiments of the present disclosure, it is possible to provide a solder paste capable of sufficiently securing solder meltability at the time of reflow even in a case where the solder paste is stored in a room temperature (25° C.) environment and a joining structure using the same.

The solder paste and joining structure of the embodiments of the present disclosure are applicable to a wide range of applications in the field of techniques for forming electric/electronic circuits. For example, the present disclosure is applicable for connection of electronic components such as CCD devices, hologram devices, and chip components, and for joining of such components to a board. Further, the present disclosure is applicable to products in which such devices, components, and boards are installed, for example, such as DVDs, cell phones, portable AV devices, and digital cameras.

What is claimed is:

1. A solder paste comprising:
a solder powder; and
a flux,
wherein the flux contains a keto acid and a hydroxy group-containing compound different from the keto acid,
the keto acid has a melting point of 60° C. or lower,
the hydroxy group-containing compound has a melting point of 60° C. or lower and has at least three hydroxy groups in the molecule, and
a content of the keto acid, a content of the hydroxy group-containing compound, and a content of the solder powder satisfy Expressions (1) and (2),
W₁×⅓≤W₂≤W₁×⅚ (1)
(W₁+W₂)/W₃×100≥2.0 (2)
where W₁ represents a weight (g) of the keto acid, W₂ represents a weight (g) of the hydroxy group-containing compound, and W₃ represents a weight (g) of the solder powder.

2. The solder paste of claim 1,
wherein the number of carboxyl groups contained in the keto acid is one.

3. The solder paste of claim 1,
wherein the hydroxy group-containing compound contains a nitrogen atom.

4. The solder paste of claim 1,
wherein Expression (3) is further satisfied:
(W₁+W₂)/W₃×100≤10.0 (3).

5. The solder paste of claim 1,
wherein when a temperature of the solder paste is 25° C., the keto acid and the hydroxy group-containing compound form a hydrogen bond.

6. The solder paste of claim 1,
wherein the solder powder contains two or more elements selected from the group consisting of Sn, Bi, In, and Ag and has a melting point of 170° C. or lower.

7. A joining structure comprising:
a first member; and
a second member,
wherein the first member and the second member each have an electrode, and
the electrode of the first member and the electrode of the second member are joined by the solder paste of claim 1.
